(19) United States
(12) Patent Application Publication
(10) Pub. No.: US 2025/0199414 A1
(43) Pub. Date: Jun. 19, 2025

(54) MICROELECTROMECHANICAL DEVICE

(71) Applicants: Robert Bosch GmbH, Stuttgart (DE); Carl Zeiss SMT GmbH, Oberkochen (DE)

(72) Inventors: Ralf NOLTEMEYER, Herrenberg (DE); Arnd KAELBERER, Schlierbach (DE); Heiko STAHL, Reutlingen (DE); Tobias HENN, Stuttgart (DE); Jan STIEDL, Pliezhausen (DE)

(21) Appl. No.: 19/073,220

(22) Filed: Mar. 7, 2025

Related U.S. Application Data
(63) Continuation of application No. PCT/EP2023/073655, filed on Aug. 29, 2023.

(30) Foreign Application Priority Data
Sep. 9, 2022 (DE) 10 2022 209 451.4

(51) Int. Cl. G03F 7/00; B81C 99/00; G02B 26/08

(52) U.S. Cl. CPC G03F 7/70116; B81C 99/004; G02B 26/0833; G03F 7/70033; G03F 7/702; B81B 2201/042; B81B 2207/012; B81C 2203/0785

(57) ABSTRACT

Microelectromechanical device with a carrier substrate having a substrate surface (100a), and plural MEMS modules (120. Each module includes an ASIC layer (140) having a front side (140a) and a rear side (140b). A baseplate (160) has a front side (160a) and a rear side (160b), a plurality of microelectromechanical components (130) have rear sides (130b). The baseplate rear side is cohesively connected to the ASIC layer front side with electrical contacts (144). The components are arranged on the baseplate front side with their component rear sides. The contacts are partly encompassed by a frame (195) arranged between baseplate and ASIC layer. The ASIC layer has an ASIC controlling the components. The ASIC is electrically connected to the components using a portion of the contacts. The modules are arranged on the substrate surface and the ASIC layer rear sides of the modules are connected to the substrate surface.

### CROSS-REFERENCE TO RELATED APPLICATION

This is a Continuation of International Application PCT/EP2023/073655, which has an international filing date of Aug. 29, 2023, and the disclosure of which is incorporated in its entirety into the present Continuation by reference. This Continuation also claims foreign priority under 35 U.S.C. § 119 (a)-(d) to and also incorporates by reference, in its entirety, German Patent Application DE 10 2022 209 451.4 filed on Sep. 9, 2022.

### FIELD

The present invention concerns the field of microelectromechanical devices, in particular micromirror arrays, and relates to a microelectromechanical device, to an illumination optical unit, to an illumination system for a projection exposure apparatus, to a corresponding projection exposure apparatus and to a method for producing a microelectromechanical device.

### BACKGROUND

Devices comprising displaceable micromirrors arranged in the manner of a matrix, known as micromirror arrays or micromirror actuators, are used nowadays in a multiplicity of devices, for example in smartphones, projectors, head-up displays, barcode readers, mask exposure units in semiconductor fabrication, and microscopes. Corresponding micromirror arrays are known, for example, from documents DE 10 2013 208 446 A1, EP 0 877 272 A1 and WO 2010/049076 A2. Disclosures regarding suitable actuator units for displacing the individual mirrors of a micromirror array, the micromirrors, are specified for example in DE 10 2013 206 529 A1, DE 10 2013 206 531 Al and DE 10 2015 204 874 A1.

### SUMMARY

According to the invention, a microelectromechanical device, an illumination optical unit comprising such a microelectromechanical device and also an illumination system and a projection exposure apparatus, each with a corresponding illumination optical unit, and a method for producing a microelectromechanical device according to the invention are proposed.

In accordance with a first aspect, a microelectromechanical device comprising a carrier substrate having a substrate surface, and a plurality of MEMS modules (MEMS: microelectromechanical system) is proposed. In this case, each of the plurality of MEMS modules comprises a, preferably exactly one, ASIC (ASIC: application-specific integrated circuit) layer having an ASIC layer front side and an ASIC layer rear side situated opposite this ASIC layer front side, a baseplate having a baseplate front side and a baseplate rear side situated opposite the baseplate front side, and a plurality of microelectromechanical components having a component rear side. The microelectromechanical components need not be identical in terms of their construction and/or their function, although this may be the case. The baseplate is arranged on the ASIC layer front side and the baseplate rear side is cohesively connected to the ASIC layer front side by way of electrical contacts. What is appropriate for this in particular is a cohesive connection via soldering or preferably sintering or eutectic bonding. By way of example, silver sintering paste can be used as sintering material. The plurality of microelectromechanical components are furthermore arranged on the baseplate front side and their component rear sides are connected to the baseplate front side. In this case, the electrical contacts between baseplate and ASIC layer are at least partly, preferably all, encompassed by at least one protective frame which is arranged between baseplate and ASIC layer and which can likewise be electrically conductive. An implementation with a plurality of protective frames in one MEMS module is feasible here, in such a case each of these protective frames encompassing a different portion of the electrical contacts between baseplate and ASIC layer, but it is preferable for there to be only exactly one protective frame per MEMS module. The ASIC layer of each of the MEMS modules has one or a plurality of ASICs (application-specific integrated circuits) for controlling the plurality of microelectromechanical components, wherein the one or the plurality of ASICs are electrically connected to the microelectromechanical components using at least one portion of the electrical contacts, wherein the electrical contacts are typically led further in the baseplates to the microelectromechanical components through electrical connections, for example vias. By way of example, in order to produce electrical connections between further electronics situated on the carrier substrate and the microelectromechanical components, the ASIC layer can optionally also comprise interposers and/or further elements besides ASICs. An ASIC layer of a MEMS module can be a continuous ASIC layer or a non-continuous ASIC layer. The term continuity of an ASIC layer means that all elements of the ASIC layer are mechanically connected to one another by way of the layer itself. Such a mechanical connection by way of the ASIC layer between two elements can be effected by the elements themselves and/or by other elements of the layer, such as, for example, ASICs, interposers, suitable connection elements, filling materials and/or joining materials. In the case of a non-continuous ASIC layer, this layer has elements such as ASICs and/or interposers, for example, which are not mechanically connected to one another by way of the layer itself. The ASIC layer thus has a gap. Electrical connections can be led further with the electrical contacts between ASIC layer and baseplate. Appropriate interposers are in particular silicon-based interposers with electrical connections, for example through-silicon vias (TSVs), such as copper-based vias (Cu vias), for example. The plurality of MEMS modules are arranged on the substrate surface of the carrier substrate and the ASIC layer rear sides of the plurality of MEMS modules are connected to the substrate surface. This connection, too, is typically embodied in cohesive fashion and is preferably effected by sintering. The further electronics on the carrier substrate can be for example further ASICs for controlling the entire electromechanical device, passive components and/or connection elements (such as plugs, cables), for example for producing an electrical connection to external control devices such as a computing unit, and for power supply purposes. The carrier substrate serves overall as a component carrier and can comprise electrical connections, for example vias for leading electrical signals from one surface of the carrier substrate through to another surface of the carrier substrate. In this regard, it can be advantageous, for example, to arrange the further electronics on a substrate surface of the carrier substrate that is situated opposite the substrate surface with the MEMS modules. The carrier substrate can for example substantially consist of a ceramic, for example an Al2O3-based ceramic.

Such a microelectromechanical device thus subdivides its plurality of microelectromechanical components into individual groups, each of which comprises a plurality of microelectromechanical components, these groups being referred to as MEMS modules in the context of this disclosure. The plurality of MEMS modules can each have for example exactly 2, 3, 4, 5, 6, 9, 12, 16, 20, 25, 30, 36, 42, 49, 56, 64, 72 or 81 of the plurality of microelectromechanical components, other numbers ≥2 also being feasible. The plurality of microelectromechanical components can be arranged for example in a rectangular grid consisting of columns and rows, for example consisting of two columns and two rows, two columns and three rows, three columns and three rows, three columns and four rows, four columns and four rows, four columns and five rows, five columns and five rows, five columns and six rows, six columns and six rows, six columns and seven rows, seven columns and seven rows, seven columns and eight rows, eight columns and eight rows, eight columns and nine rows, or nine columns and nine rows. Alternatively, a hexagonal grid is feasible, for example. An electromechanical device according to this aspect of the invention can comprise for example exactly 2, 3, 4, 5, 6, 9, 12, 16, 20, 25, 30, 36, 42, 49, 56, 64, 72 or 81 MEMS modules, other numbers ≥2 also being feasible. The MEMS modules, too, can be arranged in a rectangular grid consisting of columns and rows, for example consisting of two columns and two rows, two columns and three rows, three columns and three rows, three columns and four rows, four columns and four rows, four columns and five rows, five columns and five rows, five columns and six rows, six columns and six rows, six columns and seven rows, seven columns and seven rows, seven columns and eight rows, eight columns and eight rows, eight columns and nine rows, or nine columns and nine rows. Here, too, alternatively, a hexagonal grid is feasible, for example.

One advantageous aspect of a microelectromechanical device subdivided in this way is that a reduction of the complexity and fault susceptibility of the construction is achieved with the subdivision into MEMS modules. It has been established that a plurality of MEMS modules with a reduced number of microelectromechanical components are easier to handle in the production process than a single unit with the same total number of microelectromechanical components. In particular, the yield in the production process can be significantly increased with an approach according to this aspect the invention since the MEMS modules which include exclusively fully functional microelectromechanical components can be selected in a targeted manner during production. Furthermore, it is feasible for a multiplicity of such microelectromechanical devices according to this aspect of the invention to be connected in turn to form a superordinate unit, for example in order to cover larger areas than is practicable with a single microelectromechanical device according to this aspect of the invention. The protective frames arranged according to this aspect of the invention between the baseplates and the ASIC layers ensure that no damage can occur in the regions surrounded by the protective frames. In particular, the structures of the ASICs that lie in these regions and the electrical contacts are thus protected against damage and contaminations such as may occur during the production of a microelectromechanical device according to this aspect of invention and also during later operation. The protective frames thus serve for encapsulation from the environment. At the same time, the mechanical cohesion between ASIC layers and baseplates is increased as well. Preferably, the protective frames of the MEMS modules are embodied such that, in particular, temperature-dictated deformations of the MEMS modules are reduced.

The protective frames are furthermore preferably fashioned such that they encompass or themselves cover the entire ASIC layer top side and the entire baseplate underside. The protective frames thus preferably extend along the edges of the ASIC layer top side and the baseplate underside. Preferably, in this case, a protective frame of a MEMS module does not project laterally beyond the baseplate, in order to enable the closest possible arrangement of the MEMS modules on a carrier substrate, i.e. a high fill factor. Likewise in order to enable a high fill factor, preferably, the ASIC layer of a MEMS module also does not project laterally beyond the baseplate. The ASIC layer of a MEMS module thus preferably has dimensions identical to or smaller than those of the baseplate.

One particularly important embodiment is the use with micromirrors as microelectromechanical components. The microelectromechanical device can thus be a micromirror array, in particular. In such a case, each of the plurality of microelectromechanical components comprises a mirror element having a reflection surface for reflecting light, and a displacement unit for displacing the mirror element of the respective microelectromechanical component, wherein the one or the plurality of ASICs are configured for controlling the displacement units. In this case, displacing means a movement in relation to at least one degree of freedom. Displacing can comprise both linear movements and rotations. The mirror element can be or can comprise in particular a Bragg mirror. The displacement units can be for example electrostatic actuators, for example having comb electrodes. Appropriate actuators are for example those as described in the documents DE 10 2013 206 529 A1, DE 10 2013 206 531 A1 and DE 10 2015 204 874 A1.

Furthermore, it is particularly advantageous if each of the plurality of microelectromechanical components of each of the plurality of MEMS modules has a substantially rectangular, preferably square, base surface or a substantially hexagonal base surface. Substantially rectangular or hexagonal base surface means that relatively small deviations from a rectangular or respectively hexagonal base surface are feasible, for example owing to rounded corners and/or indentations or bulges.

In accordance with one preferred configuration of the invention, the at least one protective frame of each of the plurality of MEMS modules is a part of the cohesive connection of the baseplate rear side to the ASIC layer front side in the respective one of the plurality of MEMS modules. This enables the protective frames of a device according to this aspect of the invention to be realized particularly simply in a production process.

In order to be able to place, i.e. grip, move and/or position, the MEMS modules on the substrate surface during the production process, for example with a suitable machine, the MEMS modules must be able to be gripped without their being damaged. For this purpose, the MEMS modules can each comprise a frame which laterally delimits the MEMS module and at which a MEMS module can be gripped and subsequently moved and/or positioned. This frame can be identical with a protective frame of the respective MEMS module, but is preferably not identical therewith.

In accordance with a second aspect of the invention, an illumination optical unit for a microelectromechanical device for guiding illumination radiation to an object field is proposed, which illumination optical unit comprises at least one microelectromechanical device according to this aspect of the invention, wherein each of the plurality of microelectromechanical components comprises a mirror element having a reflection surface, and a displacement unit for displacing the mirror element of the respective microelectromechanical component, wherein the one or the plurality of ASICs are configured for controlling the displacement units. An illumination optical unit according to this aspect of the invention thus uses a microelectromechanical device according to the invention as a micromirror array. It can in particular also comprise a plurality of such micromirror arrays according to the invention, for example in order that, with an arrangement of this multiplicity of micromirror arrays, a larger overall micromirror array is implemented which makes it possible to deflect incident light beams with a larger beam diameter.

In accordance with a third aspect, an illumination system for a projection exposure apparatus is also proposed, which illumination system comprises an illumination optical unit according to this aspect of the invention and a radiation source, in particular an EUV radiation source.

In accordance with a fourth aspect, a microlithographic projection exposure apparatus is proposed which comprises an illumination optical unit according to this aspect of the invention and a projection optical unit for projecting a reticle arranged in an object field into an image field.

An illumination optical unit according to the invention, an illumination system according to the invention and a projection exposure apparatus according to the invention can be part of an EUV lithography apparatus. For these, adjustable optical paths up to a photomask (also referred to as a reticle) are advantageous, which can be realized by a micromirror array as a microelectromechanical device according to the invention in the optical path. The reflection surfaces of the mirror elements can be provided with a Bragg coating that affords particularly good reflection of the central wavelengths of the light used for exposure.

For further details regarding a possible general set-up of a corresponding projection exposure apparatus and an associated illumination optical unit and an associated illumination system, reference should be made to DE 10 2015 204 874 A1 and DE 10 2016 213 026 A1, which are hereby fully incorporated in the present application as part thereof.

In accordance with a fifth aspect of the invention, a method for producing a microelectromechanical device, preferably in accordance with the first aspect of the invention, comprising a carrier substrate and a plurality of MEMS modules, is provided. Each of the MEMS modules comprises a, preferably exactly one, ASIC layer having one or a plurality of ASICs (and optionally also other elements such as one or a plurality of interposers) and an ASIC layer front side and an ASIC layer rear side, a baseplate having a baseplate front side and a baseplate rear side, and a plurality of microelectromechanical components, wherein the baseplate is arranged on the ASIC layer front side and the baseplate rear side is connected to the ASIC layer front side. The ASIC layers of the MEMS modules can be configured as continuous ASIC layers or as non-continuous ASIC layers. The method according to this aspect of the invention involves providing a MEMS substrate having structures for the microelectromechanical components and the baseplates of the plurality of MEMS modules. The MEMS substrate provided thus comprises structures for the microelectromechanical components and for the baseplates of the plurality of MEMS modules. Such a substrate is typically present in the form of a wafer (MEMS wafer) and can be produced through a method as described in DE 10 2015 206 996 A1, for example. This likewise involves providing an ASIC substrate having structures for the ASIC layers of the microelectromechanical device, likewise typically in the form of a wafer (ASIC wafer). From these two substrates, a coupled substrate, typically in the form of a coupled wafer, is produced by connection (in the case of wafers: wafer bonding), in particular cohesive connection (for example soldering, sintering, for example using a silver sintering paste, or eutectic bonding), wherein a plurality of assigned electrical contacts and at least one, preferably exactly one, assigned protected frame between MEMS substrate and ASIC substrate are formed for each of the plurality of MEMS modules, such that for each MEMS module the at least one protective frame assigned to the MEMS module at least partly encompasses, preferably encompasses all, the electrical contacts assigned to the MEMS module. Afterwards, this coupled substrate is singulated along predefined separating lines, for example along a lattice structure, in order to obtain the plurality of MEMS modules, for example through sawing using a saw or cutting using a laser beam. Singulation can also be effected using an etching method such as deep reactive ion etching (DRIE). In this method step, the protective frames protect the region of the contacts against contaminations and possible damage, and also the structures of the respective ASIC layer that lie there. Moreover, the protective frames ensure improved cohesion of the coupled substrate before and during singulating and also after the singulation of the MEMS modules.

Furthermore, a carrier substrate is provided, on which further electronics and/or other components may already have been mounted, if appropriate. The plurality of MEMS modules are placed on a substrate surface of the carrier substrate. This is followed by cohesively connecting—for example through soldering or sintering, for example using a silver sintering paste—the ASIC layer rear sides of the plurality of MEMS modules to the substrate surface. Preferably, producing the coupled substrate is preceded by testing the microelectromechanical structures of the MEMS substrate and/or testing the structures of the ASIC substrate in order to ensure the functionality. Preferably, for ensuring the functionality, it is also possible to carry out testing of the MEMS modules after producing the coupled substrate and/or the entire completed microelectromechanical device after cohesively connecting the ASIC layer rear sides of the plurality of MEMS modules to the substrate surface.

Embodiments according to the invention offer an approach for microelectromechanical devices such as micromirror arrays, for example, which comprise a plurality of microelectromechanical components arranged on the same carrier substrate.

In particular, the yield in the production process can be significantly increased through the subdivision according to some aspects of the invention of the microelectromechanical components into individual smaller units (MEMS modules), since the individual MEMS modules can be tested in a targeted manner during production and those which include exclusively fully functional microelectromechanical components can subsequently be selected. Furthermore, the use of protective frames for encompassing important regions of the MEMS modules including relevant electrical contacts results in protection against damage and contaminations, in particular in the course of the production method according to this aspect of invention during the singulation required for fabricating the MEMS modules, and when the MEMS module is used in an aggressive environment. Such protective frames furthermore also increase the mechanical stability of the connection between MEMS substrate and ASIC substrate.

### BRIEF DESCRIPTION OF THE DRAWINGS

Embodiments of the invention are explained in more detail with reference to the drawings and the following description.

In the figures:

FIG. 1 shows a schematic illustration of a part of an exemplary microelectromechanical device according to the invention in a side view;

FIG. 2 shows a schematic illustration of a MEMS module of a second exemplary microelectromechanical device according to the invention in a side view and also a schematic view for describing the arrangement of a protective frame; and

FIG. 3 schematically shows a flow diagram of a method according to the invention for producing a microelectromechanical device.

### DETAILED DESCRIPTION

In the following description of the embodiments of the invention, identical or similar elements are designated with the same reference signs, a repeated description of these elements in individual cases being omitted. The figures illustrate the subject matter of the invention only schematically.

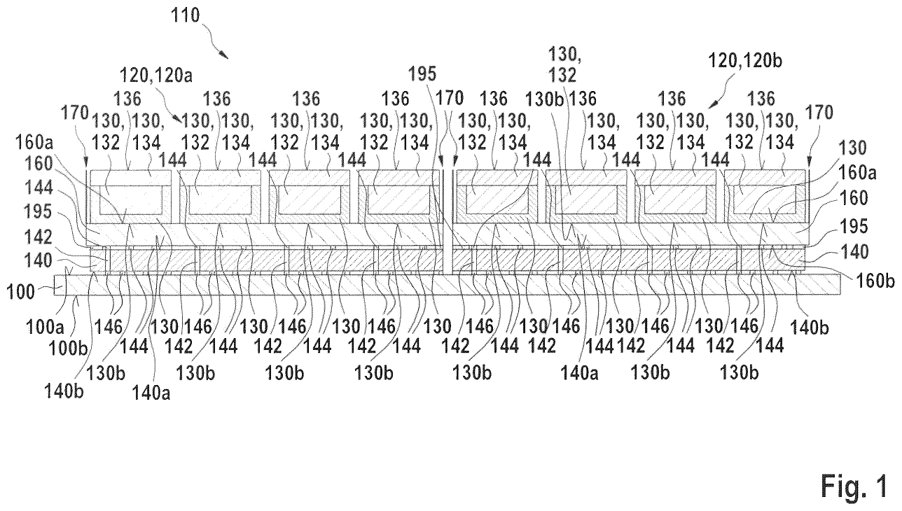

FIG. 1 shows a schematic illustration of a part of an exemplary microelectromechanical device 110 according to aspects of the invention, of a micromirror array, from the side. In the example illustrated, two MEMS modules 120 (left MEMS module: 120a, right MEMS module: 120b) are arranged on the substrate surface 100a of a carrier substrate 100, each of these MEMS modules comprising a plurality of microelectromechanical components 130, four of which in each case are illustrated in FIG. 1. The microelectromechanical components 130 are micromirrors in the case shown. These micromirrors each comprise a mirror element 134, which in turn has a reflection surface 136 for reflecting light. These mirror elements 134 can be moved with displacement units 132. ASICs serve for controlling the displacement units 132, these ASICs being arranged in the form of dies below the displacement units 132 in ASIC layers 140 and likewise being part of the respective MEMS module 120. Further electronics, for example likewise for controlling the displacement units 132, for example in the form of further ASICs, can be arranged (not illustrated) for example on the rear side 100b of the carrier substrate 100.

Within a MEMS module 120, the microelectromechanical components 130 are arranged on the front side 160a of a baseplate 160. In this case, this baseplate front side 160a is connected to the rear sides 130b of the microelectromechanical components 130. In the example illustrated, two baseplates 160 are visible, on each of which the respective four visible microelectromechanical components 130 are situated. The microelectromechanical components 130 are connected to the ASICs of the respective ASIC layer 140 by way of electrical contacts 144. The ASICs of the ASIC layers 140 in turn can be connected to further electronics (not illustrated) by way of electrical contacts 146, which further electronics can be arranged on the carrier substrate 100, for example. Moreover, through-silicon vias (TSVs) 142 can exist in the ASIC layers 140, for example, and can serve for example for producing electrical connections between such further electronics on the carrier substrate 100 and the microelectromechanical components 130. Such vias 142 can also be implemented for example through interposers, which can likewise be part of the ASIC layers 140, or with the dies of the ASICs.

Furthermore, in FIG. 1, a protective frame 195 is visible for each of the two MEMS modules 120 shown, this protective frame protecting the region between the baseplates 160 and the ASIC layer 140 and thus also the electrical contacts 144 (electrical contacts between ASICs and baseplate and also electrical contacts as continuations of vias 142) against damage. Furthermore, optionally, a further frame 170 can in each case be part of the MEMS modules 120, which further frame laterally delimits the MEMS modules 120 and enables the MEMS modules 120 to be placed on the carrier substrate 100, without risking damage to the MEMS modules 120 and in particular the microelectromechanical components 130 thereof, or protects them against ingress of particles.

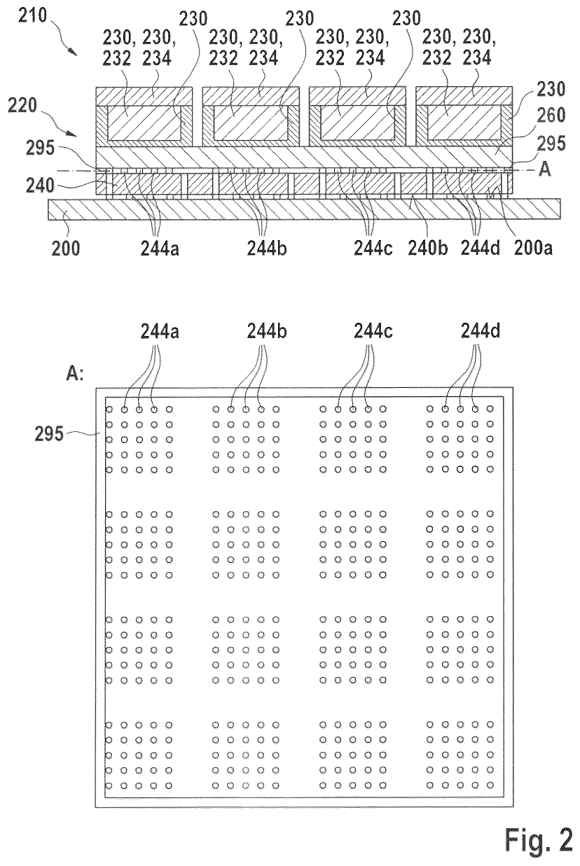

FIG. 2 shows a schematic illustration of a MEMS module 220 of a second exemplary microelectromechanical device 210 according to the invention in a side view in an upper subfigure and also a schematic view of a sectional plane A for describing the arrangement of a protective frame 295 in the MEMS module 220 in a lower subfigure. As in FIG. 1, the MEMS module 220 illustrated here also has four microelectromechanical components 230, visible in the side view in the upper subfigure. Overall, as is evident from the lower subfigure, the MEMS module 220 illustrated has 16 microelectromechanical components 230, each having a displacement unit 232 for displacing mirror elements 234 having reflection surfaces. Situated between an ASIC layer 240 and the baseplate 260 there are electrical contacts 244a, 244b, 244c, 244d, which are in part continuations of electrical connections such as vias 142 in the ASIC layer 240. At least partly, these electrical contacts 244a, 244b, 244c, 244d are encompassed by a protective frame 295. Preferably and as shown in FIG. 2, all the electrical contacts 244a, 244b, 244c, 244d are situated within the region defined by the protective frame 295. The entire MEMS module 220 is arranged on a carrier substrate 200, for example substantially consisting of a ceramic, wherein the ASIC layer rear side 240b of the ASIC layer 240 is for example cohesively connected to the substrate surface 200a of the carrier substrate 200.

The sectional plane A situated at the level of the electrical contacts 244a, 244b, 244c, 244d is illustrated in a plan view in the lower subfigure. It is discernible that the exemplary MEMS module 220 consists of four times four microelectromechanical components 230, to each of which 25 electrical contacts 244a, 244b, 244c, 244d are assigned.

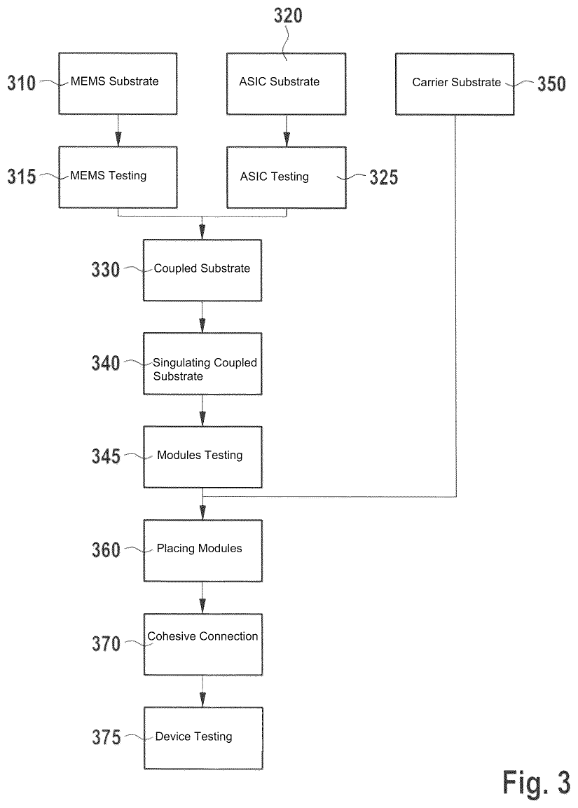

Finally, FIG. 3 schematically shows a flow diagram of a method according to the invention for producing a microelectromechanical device 110, 210, comprising a carrier substrate 100, 200 and a plurality of MEMS modules 120, 220, wherein each of the MEMS modules 120, 220 comprises an ASIC layer 140, 240 comprising one or a plurality of ASICs having an ASIC layer front side 140a, 240a and an ASIC layer rear side 140b, 240b, a baseplate 160, 260 having a baseplate front side 160a and a baseplate rear side 160b, and a plurality of microelectromechanical components 130, 230, wherein the baseplate 160, 260 is arranged on the ASIC layer front side 140a and the baseplate rear side 160b is connected to the ASIC layer front side 140a. This involves providing 310 a MEMS substrate having structures for the microelectromechanical components 130, 230 and the baseplates 160, 260 of the plurality of MEMS modules 120, 220. This likewise involves providing 320 an ASIC substrate having structures for the ASIC layers 140, 240 of the plurality of MEMS modules 120, 220. From these, a coupled substrate is produced 330 by cohesive connection, for example soldering, sintering or eutectic bonding, wherein a plurality of assigned electrical contacts 144 between MEMS substrate and ASIC substrate are formed for each of the plurality of MEMS modules 120, 220. Afterwards, this coupled substrate is singulated 340 along predefined separating lines such as, for example, a lattice structure, in order to obtain the plurality of MEMS modules 120, 220. Furthermore, a carrier substrate 100, 200 is provided 350, on which further electronics may be mounted, if appropriate. The plurality of MEMS modules 120, 220 are placed 360 on the substrate surface 100a, 200a of the carrier substrate 100, 200. Finally, the ASIC layer rear sides 140b of the plurality of MEMS modules 120, 220 are cohesively connected to the substrate surface 100a, 200a in step 370.

Preferably, producing the coupled substrate is preceded by testing 315 the microelectromechanical structures of the MEMS substrate and/or testing 325 the structures of the ASIC substrate in order to ensure the functionality. Additionally or alternatively, for ensuring the functionality, it is also possible to carry out testing 345 of the MEMS modules 120, 220 after producing the coupled substrate and/or testing 375 of the entire completed microelectromechanical device 110, 210 after cohesively connecting the ASIC layer rear sides 140b of the plurality of MEMS modules 120, 220 to the substrate surface 100a.

The invention is not limited to the exemplary embodiments described here and the aspects highlighted herein. On the contrary, a large number of modifications that are within the ability of a person skilled in the art are possible within the scope specified by the claims. The applicant seeks, therefore, to cover all such modifications a fall within the spirit and scope of the invention, as defined by the appended claims, and equivalents thereof.

What is claimed is:

1. Microelectromechanical device comprising a carrier substrate having a substrate surface, and a plurality of microelectromechanical system (MEMS) modules,
wherein each of the plurality of MEMS modules comprises an application-specific integrated circuit (ASIC) layer having an ASIC layer front side and an ASIC layer rear side, a baseplate having a baseplate front side and a baseplate rear side, and a plurality of microelectromechanical components each having a component rear side,
wherein the baseplate is arranged on the ASIC layer front side and the baseplate rear side is cohesively connected to the ASIC layer front side with electrical contacts and the plurality of microelectromechanical components are arranged on the baseplate front side and the component rear sides are connected to the baseplate front side,
wherein the electrical contacts are at least partly encompassed by at least one protective frame arranged between the baseplate and the ASIC layer,
wherein the ASIC layer has at least one ASIC for controlling the plurality of microelectromechanical components, wherein the at least one ASIC is electrically connected to the microelectromechanical components using at least one portion of the electrical contacts, and
wherein the plurality of MEMS modules are arranged on the substrate surface and the ASIC layer rear sides of the plurality of MEMS modules are connected to the substrate surface.

2. Microelectromechanical device according to claim 1, wherein each of the plurality of microelectromechanical components comprises a mirror element having a reflection surface, and a displacement unit for displacing the mirror element of the respective microelectromechanical component, wherein the at least one ASIC is configured to control the displacement unit.

3. Microelectromechanical device according to claim 1, wherein each of the plurality of MEMS modules has exactly 2, 3, 4, 6, 9, 12, 16, 20, 25, 30, 36, 42, 49, 56, 64, 72 or 81 of the plurality of microelectromechanical components.

4. Microelectromechanical device according to claim 1, wherein each of the plurality of microelectromechanical components of each of the plurality of MEMS modules has a substantially rectangular base surface or a substantially hexagonal base surface.

5. Microelectromechanical device according to claim 4, wherein each of the plurality of microelectromechanical components of each of the plurality of MEMS modules has a square base surface.

6. Microelectromechanical device according to claim 1, wherein the at least one protective frame of each of the plurality of MEMS modules is a part of the cohesive connection of the baseplate rear side to the ASIC layer front side in respective ones of the plurality of MEMS modules.

7. Illumination optical unit for a projection exposure apparatus for guiding illumination radiation to an object field, comprising at least one microelectromechanical device according to claim 2.

8. Illumination system for a projection exposure apparatus, comprising an illumination optical unit according to claim 7 and a radiation source.

9. Illumination system as claimed in claim 8, wherein the radiation source is an extreme ultraviolet (EUV) radiation source.

10. Microlithographic projection exposure apparatus, comprising an illumination optical unit according to claim 7 and a projection optical unit for projecting a reticle arranged in an object field into an image field.

11. Method for producing a microelectromechanical device comprising a carrier substrate and a plurality of microelectromechanical system (MEMS) modules, wherein each of the MEMS modules comprises an application specific integrated circuit (ASIC) layer comprising at least one ASIC having an ASIC layer front side and an ASIC layer rear side, a baseplate having a baseplate front side and a baseplate rear side, and a plurality of microelectromechanical components, wherein the baseplate is arranged on the ASIC layer front side and the baseplate rear side is connected to the ASIC layer front side, said method comprising:
a. providing a MEMS substrate having structures for the microelectromechanical components and for the baseplates of the plurality of MEMS modules;
b. providing an ASIC substrate having structures for the ASIC layers of the plurality of MEMS modules;
c. producing a coupled substrate by cohesively connecting the MEMS substrate to the ASIC substrate, wherein a plurality of assigned electrical contacts and at least one assigned protective frame between the MEMS substrate and the ASIC substrate are formed for each of the plurality of MEMS modules, such that for each of the MEMS modules the at least one protective frame assigned to the MEMS module at least partly encompasses the electrical contacts assigned to the MEMS module;
d. singulating the coupled substrate along predefined separating lines to obtain the plurality of MEMS modules;
e. providing the carrier substrate;
f. placing the plurality of MEMS modules on a substrate surface of the carrier substrate; and
g. cohesively connecting the ASIC layer rear sides of the plurality of MEMS modules to the substrate surface.

12. Method according to claim 11,
prior to said producing the coupled substrate, testing the structures of the MEMS substrate and/or testing the structures of the ASIC substrate;
and/or subsequent to said producing the coupled substrate, testing (345) the MEMS modules; and/or
subsequent to said cohesively connecting the ASIC layer rear sides of the plurality of MEMS modules to the substrate surface, testing the microelectromechanical device produced.
